(19) United States
(12) Patent Application Publication
(10) Pub. No.: US 2011/0266033 A1
(43) Pub. Date: Nov. 3, 2011

(54) MULTILAYER BOARD

(75) Inventors: Kazuo TADA, Kariya-city (JP); Yoshitarou Yazaki, Anjo-city (JP); Gentarou Masuda, Kariya-city (JP); Yasuhiro Tanaka, Chiryu-city (JP); Eijirou Miyagawa, Kariya-city (JP)

(73) Assignee: DENSO CORPORATION, Kariya-city (JP)

(21) Appl. No.: 13/081,545

(22) Filed: Apr. 7, 2011

(30) Foreign Application Priority Data
Apr. 28, 2010 (JP) 2010-103516
Aug. 6, 2010 (JP) 2010-177169

(51) Int. Cl. H05K 1/11

(52) U.S. Cl. 174/251

(57) ABSTRACT

A multilayer board includes a thermoplastic resin film layer, a pattern layer layered on the thermoplastic resin film layer, and a conductor pattern. The thermoplastic resin film layer is made of a plurality of thermoplastic resin films layered with each other, and has two adhesive layers and an interlayer located between the two adhesive layers. Each of the adhesive layers has an interlayer connector passing through the adhesive layer in a thickness direction. The conductor pattern is located on at least one of the pattern layer and the interlayer at a position opposing to the interlayer connector.

### CROSS REFERENCE TO RELATED APPLICATION

This application is based on Japanese Patent Application No. 2010-103516 filed on Apr. 28, 2010 and Japanese Patent Application No. 2010-177169 filed on Aug. 6, 2010, the disclosures of which are incorporated herein by reference in their entirety.

### BACKGROUND OF THE INVENTION

1. Field of the Invention

The present invention relates to a multilayer board.

2. Description of Related Art

JP-A-2006-203114 describes a multilayer board produced by pressing a layered member with heat. The layered member is constructed by alternately layering pattern layers and thermoplastic resin film layers. The pattern layer is made of resin film having a conductor pattern. The thermoplastic resin film layer is made of thermoplastic resin film, which is softened by being heated.

For example, the multilayer board has a first pattern layer, a thermoplastic resin film layer layered on the first pattern layer, and a second pattern layer layered on the thermoplastic resin film layer. The first pattern layer is made of a thermosetting resin film, and a lower face of the thermosetting resin film has a conductor pattern. The second pattern layer has a resin film, and an upper face of the resin film has a conductor pattern. Each of the pattern layers and the thermoplastic resin film layer has an interlayer connector made of conductive material. The interlayer connector is produced by filling conductive paste in a via hole, and by hardening the filled paste.

For example, a multilayer board is produced by layering a pattern layer on a thermoplastic resin film layer, after the thermoplastic resin film layer is constructed by layering plural thermoplastic resin films having interlayer connector.

However, reliability of interlayer connection between the films may, be low in this case.

If the thermoplastic resin film layer is layered on a face of the pattern layer not having the conductor pattern, the interlayer connector of the thermoplastic resin film layer is directly connected to the interlayer connector of the pattern layer without the conductor pattern.

If sufficient compressive force is not applied to the interlayer connector of the thermoplastic resin film layer while a heating-and-pressing treatment is performed, the reliability of interlayer connection will be lowered in the thermoplastic resin film layer.

### SUMMARY OF THE INVENTION

In view of the foregoing and other problems, it is an object of the present invention to provide a multilayer board.

According to an example of the present invention, a multilayer board includes a thermoplastic resin film layer, a pattern layer and a conductor pattern. The thermoplastic resin film layer has a plurality of thermoplastic resin films layered with each other. The thermoplastic resin film is softened when heated to have a predetermined temperature. The pattern layer is layered on the thermoplastic resin film layer, and has a low-flowability resin film. A flowability of the low-flowability resin film is lower than that of the thermoplastic resin film at the predetermined temperature. The conductor pattern has a predetermined thickness. The thermoplastic resin film layer has two adhesive films and an interlayer located between the two adhesive films. The interlayer has a first interlayer connector passing through the interlayer in a thickness direction. Each of the adhesive films has a second interlayer connector passing through the adhesive film in the thickness direction. The second interlayer connector is electrically connected to the first interlayer connector. The conductor pattern is located between the pattern layer and the interlayer of the thermoplastic resin film layer, and opposes to the second interlayer connector in the thickness direction.

Accordingly, reliability of interlayer connection can be raised in the multilayer board.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic cross-sectional view illustrating a multilayer board according to a first embodiment;

FIGS. 2A-2C are views illustrating a process of forming each film of a thermoplastic resin film, layer of the multilayer board;

FIGS. 3A-3G are views illustrating a process of forming each film of a first pattern layer of the multilayer board;

FIGS. 4A-4C are views illustrating a process of forming each film of a second pattern layer of the multilayer board;

FIG. 5 is a view illustrating a process of producing the multilayer board;

FIG. 6 is a schematic cross-sectional view illustrating a multilayer board according to a second embodiment;

FIGS. 7A-7C are views illustrating a process of forming each film of a thermoplastic resin film layer of the multilayer board of the second embodiment;

FIG. 8 is a view illustrating a process of producing the multilayer board of the second embodiment;

FIG. 9 is a schematic cross-sectional view illustrating a multilayer board according to a third embodiment;

FIGS. 10A-10C are views illustrating a process of forming each film of a thermoplastic resin film layer of the multilayer board of the third embodiment;

FIG. 11 is a view illustrating a process of producing the multilayer board of the third embodiment;

FIG. 12 is a schematic cross-sectional view illustrating a multilayer board according to a fourth embodiment;

FIGS. 13A-13C are views illustrating a process of forming each film of a thermoplastic resin film layer of the multilayer board of the fourth embodiment;

FIG. 14 is a view illustrating a process of producing the multilayer board of the fourth embodiment; and

FIG. 15A is a schematic cross-sectional view illustrating an interlayer of a thermoplastic resin film layer of a multilayer board according to a fifth embodiment, and FIG. 15B is a schematic cross-sectional view illustrating a first pattern layer of the multilayer board of the fifth embodiment.

### DETAILED DESCRIPTION OF PREFERRED EMBODIMENT

### First Embodiment

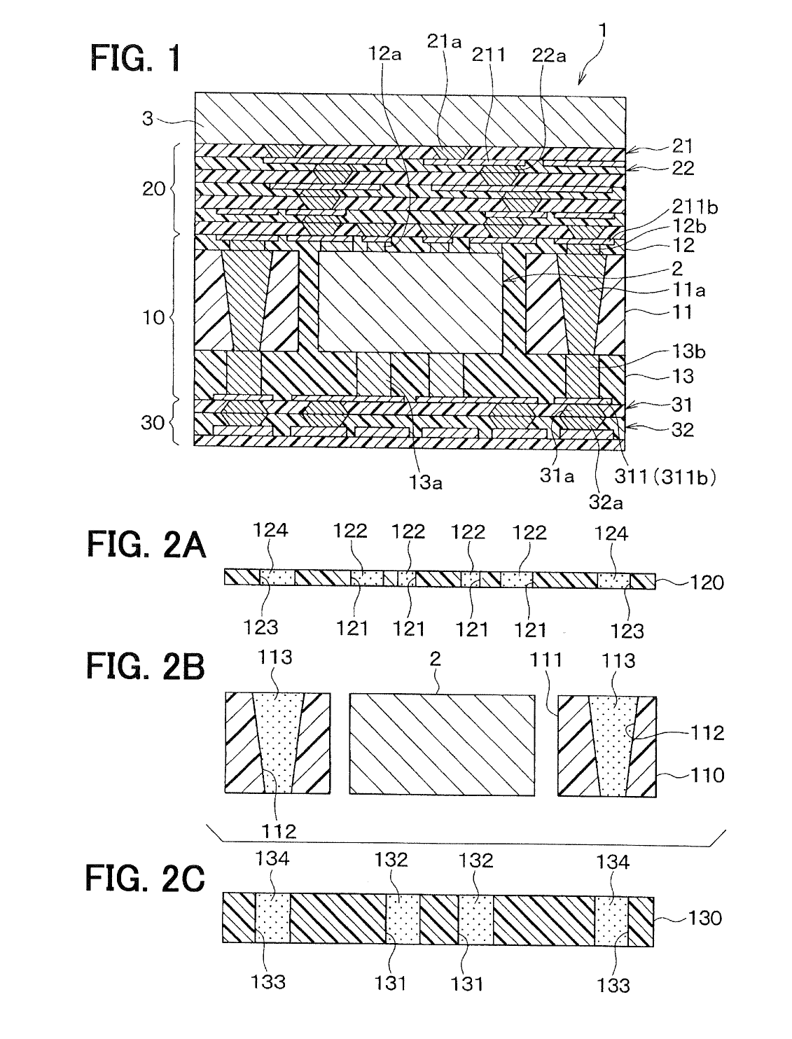

A first embodiment will be described with reference to FIGS. 1-5.

As shown in FIG. 1, a multilayer board 1 includes an electronic component 2 such as chip, for example made of semiconductor. The multilayer board 1 is produced by pressing plural resin films with heat.

The multilayer board 1 is mainly constructed by a thermoplastic resin film layer 10, a first pattern layer 20, a second pattern layer 30 and a heat sink 3.

The thermoplastic resin film layer 10 is made of plural thermoplastic resin films layered with each other as an insulating base material. The thermoplastic resin film layer 10 includes three, for example, thermoplastic resin films in the present embodiment.

Specifically, the thermoplastic resin film layer 10 includes a first adhesive layer 12, a second adhesive layer 13 and an interlayer 11 located between the adhesive layers 12, 13. The adhesive layer 12 is made of an adhesive film 120 of FIG. 2A, and the adhesive layer 13 is made of an adhesive film 130 of FIG. 2C. The interlayer 11 is made of an interlayer film 110 of FIG. 2B.

The interlayer 11 is a layer to accommodate the electronic component 2.

The interlayer 11 has a first connector 11a made of conductive material. The connector 11a penetrates the interlayer 11 in a thickness direction.

The adhesive layer 12, 13 has a component connector 12a, 13a made of conductive material. The connector 12a, 13a penetrates the layer 12, 13 in a thickness direction, and is electrically connected to the electronic component 2 disposed in the interlayer 11. The connector 12a of the first adhesive layer 12 is electrically connected to an electrode terminal (not shown) of the component 2.

The adhesive layer 12, 13 has a second connector 12b, 13b made of conductive material. The connector 12b, 13b penetrates the layer 12, 13 in the thickness direction, and is electrically connected to the first connector 11a of the interlayer 11.

The first adhesive layer 12 is located on the upper side of FIG. 1, and the second adhesive layer 13 is located on the lower side of FIG. 1, for example.

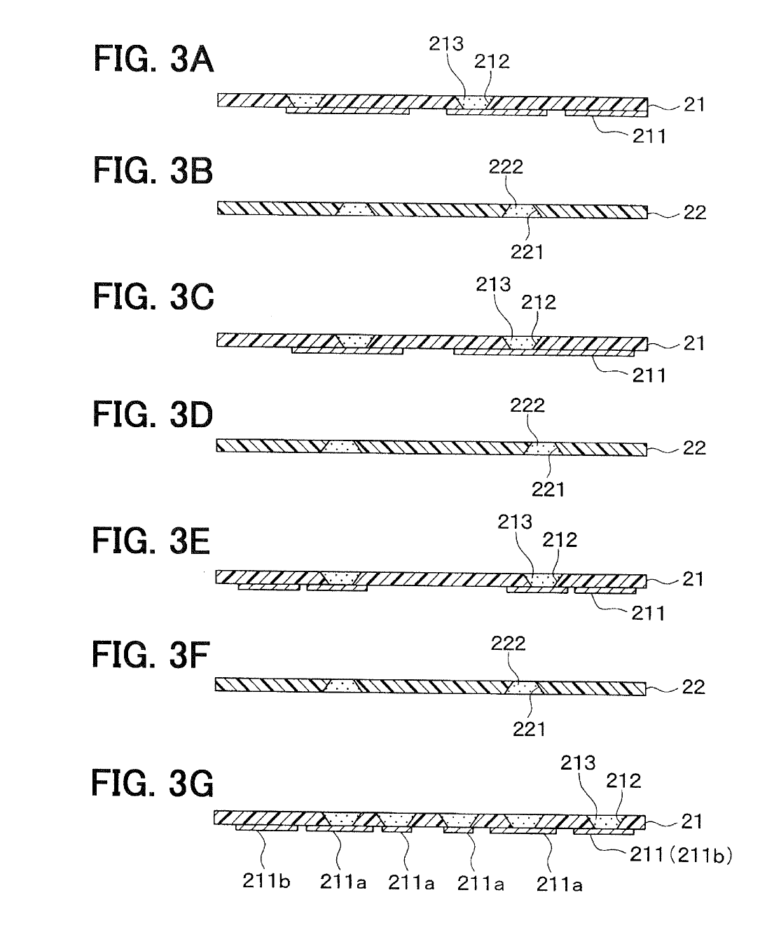

The first pattern layer 20 is located on the upper side of the thermoplastic resin film layer 10 in FIG. 1, and has pattern films 21 and adhesive films 22 alternately layered with each other. As shown in FIG. 3A, a lower face of the pattern film 21 has a conductor pattern 211 made of copper foil. The first pattern layer 20 is constructed by alternately layering four of the pattern films 21 and three of the adhesive films 22, for example. The number of the films 21, 22 is suitably changeable depending on the purpose.

As shown in FIG. 1, the film 21, 22 of the first pattern layer 20 has a third connector 21a, 22a made of conductive material. The connector 21a, 22a penetrates the film 21, 22 in the thickness direction, and electrically connects the conductor patterns 211 with each other.

Further, as shown in FIGS. 3A, 3C, 3E and 3G, a lower face of the film 21 of the first pattern layer 20 opposing to the thermoplastic resin film layer 10 has the conductor pattern 211.

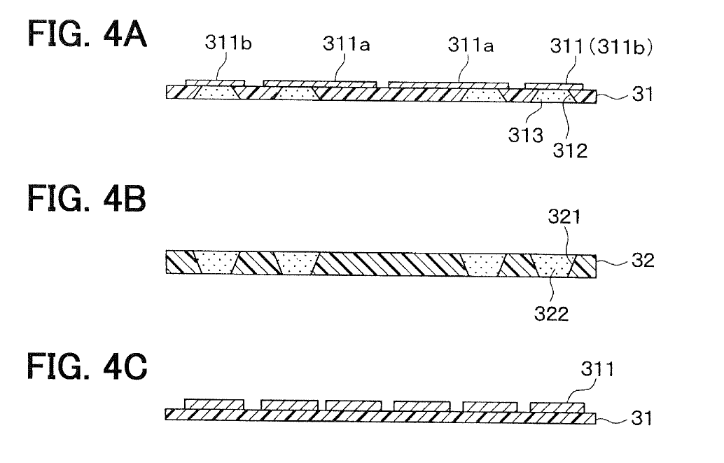

The second pattern layer 30 is located on the lower side of the thermoplastic resin film layer 10 of FIG. 1, and has pattern films 31 and adhesive films 32 alternately layered with each other. As shown in FIGS. 4A and 4C, an upper face of the pattern film 31 has a conductor pattern 311 made of copper foil. The second pattern layer 30 is constructed by alternately layering two of the pattern films 31 and one of the adhesive film 32, for example. The number of the films 31, 32 is suitably changeable depending on the purpose.

As shown in FIG. 1, the film 31, 32 of the second pattern layer 30 has a fourth connector 31a, 32a made of conductive material. The connector 31a, 32a penetrates the film 31, 32 in the thickness direction, and electrically connects the conductor patterns 311 with each other.

Further, as shown in FIGS. 4A and 4C, an upper face of the film 31 of the second pattern layer 30 opposing to the thermoplastic resin film layer 10 has the conductor pattern 311.

The heat sink 3 corresponds to a heat emitting portion to radiate heat outside when heat is emitted from the electronic component 2 corresponding to a heating element. The heat sink 3 is located on a face of the first pattern layer 20 opposite from the thermoplastic resin film layer 10.

A producing process of the multilayer board 1 will be described below. The producing process includes a process of preparing the interlayer film 110 of FIG. 2B corresponding to the interlayer 11 of the thermoplastic resin film layer 10.

A thermoplastic resin film having a thickness approximately equal to that of the electronic component 2 is prepared as an insulating base material. The thermoplastic resin film is softened by being heated with a predetermined temperature, and a flowability of the thermoplastic resin film is relatively low while being pressed with heat.

A component accommodation hole 111 is formed in the thermoplastic resin film by laser beam machining or press working, for example A size of the hole 111 is, equivalent to that of the electronic component 2. The electronic component 2 is accommodated in the accommodation hole 111 in a manner that the electrode terminal of the electronic component 2 is located on the upper side.

Further, a via hole 112 is defined in the thermoplastic resin film by laser beam machining, for example. The via hole 112 passes through the thickness direction. An electric conduction paste 113 is filled in the via hole 112 using a screen printer, for example. Thus, the interlayer film 110 is produced.

The paste 113 is made of metal particles containing tin and silver, for example, and solvent for adjusting viscosity. The metal particles are sintered into conductive material corresponding to the first interlayer connector 11a, and the solvent volatilizes, in a pressing-and-heating process.

The via hole 112 has a taper and conical shape. Alternatively, the via hole 112 may have a cylindrical shape, for example.

A process of forming the adhesive film 120 of FIG. 2A is explained below.

A thermoplastic resin film is prepared as an insulating base material. The thermoplastic resin film is softened by being heated with a predetermined temperature, and a flowability of the thermoplastic resin film is relatively high while being pressed with heat. For example, the thermoplastic resin film is made of polyetheretherketone resin and polyetherimide resin. Via holes 121, 123 passing through the thickness direction are defined in the thermoplastic resin film by laser beam machining.

Electric conduction paste 122, 124 is filled in the via hole 121, 123, respectively, using a screen printer, for example. Thus, the adhesive film 120 is produced. The paste 122, 124 may be made of the same material as the paste 113 of the interlayer film 110.

When the adhesive film 120 is layered on the interlayer film 110, a position of the via hole 121 overlaps with a position of the electrode terminal of the electronic component 2 in the thickness direction, and a position of the via hole 123 overlaps with a position of the via hole 112 in the thickness direction.

A diameter of the via hole 121 is set smaller than that of the via hole 123, because a pitch of the electrode terminal of the electronic component 2 is recently made smaller.

As shown in FIGS. 2A and 2C, a thickness of the adhesive film 120 is set smaller than that of the adhesive film 130. Therefore, the via hole 121 having the smaller diameter can be accurately filled with the paste 122.

A process of forming the adhesive film 130 of FIG. 2C is explained below.

A thermoplastic resin film is prepared as an insulating base material. A thickness of the film for the adhesive film 130 is larger than that for the adhesive film 120, while the adhesive film 130 is made of the same material as the adhesive film 120.

Via holes 131, 133 passing through the thickness direction are formed in the thermoplastic resin film by laser beam machining. Electric conduction paste 132, 134 is filled in the via hole 131, 133, respectively, using a screen printer, for example. Thus, the adhesive film 130 can be produced.

When the adhesive film 130 is layered on the interlayer film 110, a position of the via hole 131 overlaps with a position of the electrode terminal of the electronic component 2 in the thickness direction, and a position of the via hole 133 overlaps with a position of the via hole 112 in the thickness direction. The paste 132, 134 may be made of the same material as the paste 113 of the interlayer film 110.

A process of forming the pattern film 21 of FIGS. 3A, 3C, 3E and 3G is explained below.

An insulating base material of the film 21 is made of low-flowability resin film. A flowability of the pattern film 21 is lower than that of the film 120, 130, 110 in a pressing-and-heating process. The low-flowability resin film is made of thermosetting resin, for example. Alternatively, the low-flowability resin film is made of resin having a melting point higher than that of the film 110, 120, 130, for example. Alternatively, the low-flowability resin film is made of thermoplastic resin having much inorganic filler than the film 110, 120, 130. In the present embodiment, the low-flowability resin film is made of polyimide resin having thermosetting property, for example.

A copper foil is layered on a lower face of the resin film, and the predetermined conductor pattern 211 is formed by etching the copper foil. Further, a via hole 212 is formed using laser beam machining, and electric conduction paste 213 is filled in the via hole 212 using a screen printer, for example. Thus, the pattern film 21 can be produced.

A process of forming the adhesive film 22 of FIGS. 3B, 3D and 3F is explained below.

An insulating base material of the film 22 is a thermoplastic resin film, similar to the adhesive film 120, 130. A via hole 221 passing through the thickness direction is formed in the thermoplastic resin film by laser beam machining. Electric conduction paste 222 is filled in the via hole 221 using a screen printer, for example. Thus the adhesive film 22 can be produced.

A process of forming the pattern film 31 of FIGS. 4A and 4C is explained.

An insulating base material of the film 31 is a resin film similar to the film 21. A copper foil is layered on an upper face of the resin film, and the predetermined conductor pattern 311 is formed by etching the copper foil. A via hole 312 is formed in the film 31 of FIG. 4A by laser beam machining, and electric conduction paste 313 is filled in the via hole 312 using a screen printer, for example. Thus, the pattern film 31 can be produced.

A process of forming the adhesive film 32 of FIG. 4B is explained.

An insulating base material of the film 32 is a resin film, similar to the film 22. A via hole 321 is formed in the resin film by laser beam machining, and electric conduction paste 322 is filled in the via hole 321 using a screen printer, for example. Thus, the adhesive film 32 can be produced.

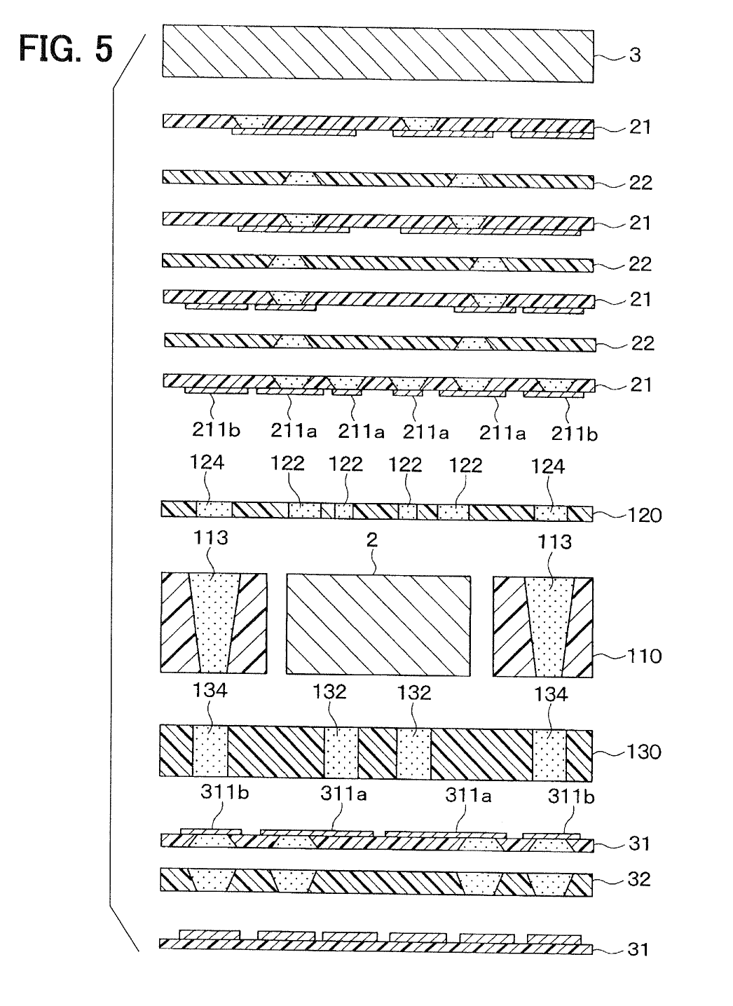

The films 110, 120, 130, 21, 22, 31 and 32 are layered into a layered member of FIG. 5 in a layering process.

At this time, the conductor pattern 211a, 211b of the film 21 located at the lowest position in the first pattern layer 20 is made contact with the paste 122, 124 of the film 120, respectively. Further, the conductor pattern 311a, 311b of the film 31 located at the highest position in the second pattern layer 30 is made contact with the paste 132, 134 of the film 130, respectively.

The layered member of FIG. 5 is arranged in a pressing machine (not shown). The pressing machine heats and presses the layered member with predetermined pressure, temperature and time. This heating-and-pressing process is performed with a pressure of 3-5 MPa (preferably about 4 MPa), temperature of 320° C. and a period of 3 hours, for example.

The heat sink 3 is mounted to the upper face of the first pattern layer 20 after the heating-and-pressing process is finished, as shown in FIG. 5. Thus, the multilayer board 1 of FIG. 1 can be produced.

In the heating-and-pressing process, the pattern films 21 of the first pattern layer 20 are bonded with each other by the adhesive film 22, and the pattern films 31 of the second pattern layer 30 are bonded with each other by the adhesive film 32. Similarly, the pattern film 21 located at the lowest position in the first pattern layer 20 and the upper face of the interlayer film 110 are bonded with each other by the adhesive film 120. The pattern film 31 located at the highest position in the second pattern layer 30 and the lower face of the interlayer film 110 are bonded with each other by the adhesive film 130.

Further, the paste 213, 222 of the first pattern layer 20 is sintered, so as to form the third connector 21a, 22a. The paste 313, 322 of the second pattern layer 30 is sintered, so as to form the fourth connector 31a, 32a.

The paste 113, 122, 124, 132, 134 of the film 110, 120, 130 is sintered, so as to form the connector 11a, 12a, 12b, 13a, 13b.

Further, in the heating-and-pressing process, resin contained in the film 120, 130 becomes flowable. Therefore, the flowable resin is filled into a cavity defined between the electronic component 2 and the accommodation hole 111, so that the electronic component 2 is sealed. The cavity is generated by tolerance between the electronic component 2 and the accommodation hole 111.

According to the present embodiment, the conductor pattern 211b opposing to the connector 12b is formed on the face of the pattern film 21, and the conductor pattern 311b opposing to the connector 13b is formed on the face of the pattern film 31.

Therefore, in the heating-and-pressing process, the paste 124, 134 of the adhesive film 120, 130 is compressed by the thickness of the conductor pattern 211b, 311b. That is, the compressive force applied to the second connector 12b, 13b is increased in the heating-and-pressing process.

Thus, void (cave) can be prevented from being generated in the second connector 12b, 13b, so that reliability of interlayer connection can be raised in the thermoplastic resin film layer 10.

### Second Embodiment

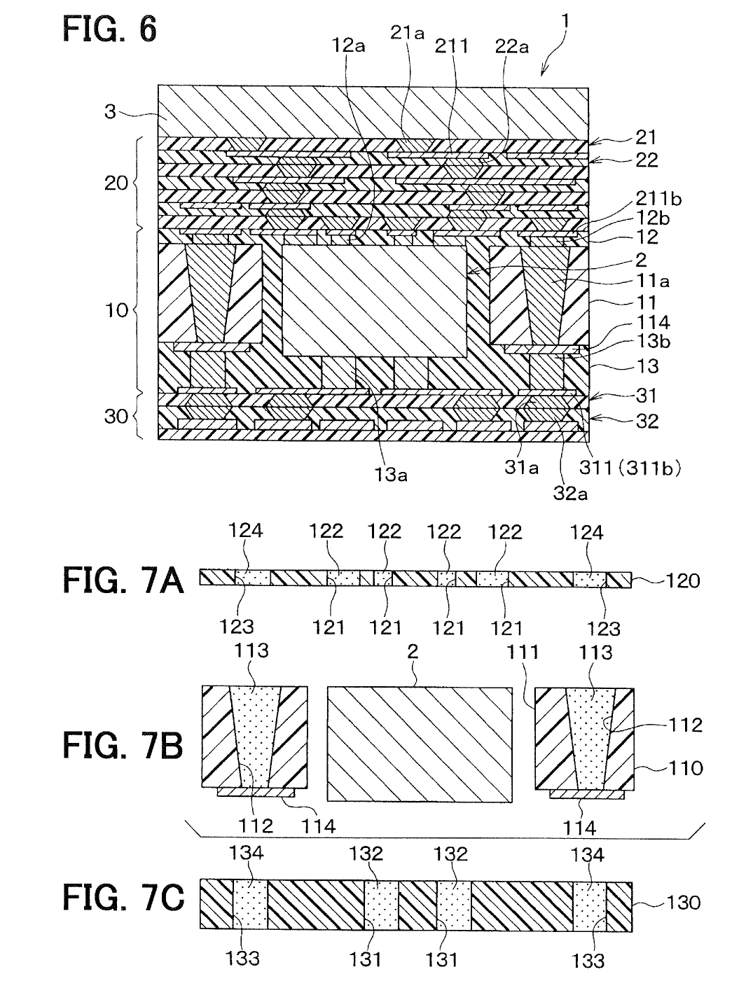

A second embodiment will be described with reference to FIGS. 6-8.

In a case where the connector 11a, 12b, 13b is constructed by the paste 113, 124, 134, when the thickness of the adhesive layer 12 is smaller than that of the adhesive layer 13, the reliability of interlayer connection may become lower in the connector 13b, compared with the connector 12b.

Usually, if a ratio of a thickness of a layer to have the via hole to a diameter of the via hole has a value within a predetermined range, paste is properly filled in the via hole. The diameter of the via hole is made larger as the thickness of the layer becomes larger. Therefore, an amount of the paste filled in the via hole becomes larger as the thickness of the layer becomes larger.

Solvent contained in the paste volatizes while the metal particles are sintered. Therefore, void is easily generated in an interlayer connector having much paste, so that the reliability of the interlayer connection may be lowered in the interlayer connector having much paste, compared with an interlayer connector having less paste.

Therefore, in the heating-and-pressing process, compressive force applied to the connector 13b is required to be larger than that applied to the connector 12b.

Further, especially when the interlayer 11 is configured to accommodate the electronic component 2 like the first embodiment, the reliability of the interlayer connection may be lowered in the connector 13b of the thick layer 13 compared with the connector 12b of the thin layer 12.

As described in the first embodiment, resin of the adhesive, layer 12, 13 flows into the clearance between the accommodation hole 111 of the interlayer film 110 and the electronic component 2 in the heating-and-pressing process, so that the component 2 is sealed inside of the thermoplastic resin film layer 10.

At this time, the thickness of the adhesive layer 12, 13 becomes smaller because resin flows into the clearance between the interlayer 11 and the component 2. Further, the second interlayer connector 12b, 13b may have a protruding shape, so that the reliability of the interlayer connection can be made better in the thermoplastic resin film layer 10.

However, a ratio of a resin amount flowing into the clearance between the interlayer 11 and the electronic component 2 is smaller in the thick layer 13 compared with the thin layer 12. Therefore, the thickness of the adhesive layer 13 is less affected even if resin flows into the clearance between the interlayer 11 and the electronic component 2.

Therefore, when the electronic component 2 is disposed in the interlayer 11, the connector 13b of the thick layer 13 easily has void than the connector 12b of the thin layer 12, so that the reliability of the connector 13b may be lowered.

According to the present embodiment, as shown in FIG. 6, a conductor pattern 114 is arranged on a face of the interlayer 11 opposing to the second connector 13b of the thick layer 13.

A producing process of an interlayer film 110 of FIG. 7B corresponding to the interlayer 11 of the thermoplastic resin film layer 10 will be described below. A thermoplastic resin film is prepared as an insulating base material. The electronic component 2 is accommodated in the accommodation hole 111, and the paste 113 is filled in the via hole 112.

Further, a copper foil is layered on a lower face of the base film, and etching is performed to the copper foil. Thus, the conductor pattern 114 is defined at the position opposing to the connector 13b, so that the film 110 can be produced. The base film has a predetermined thickness approximately equal to that of the electronic component 2. The conductor pattern 114 corresponds to a base part of the via hole 112.

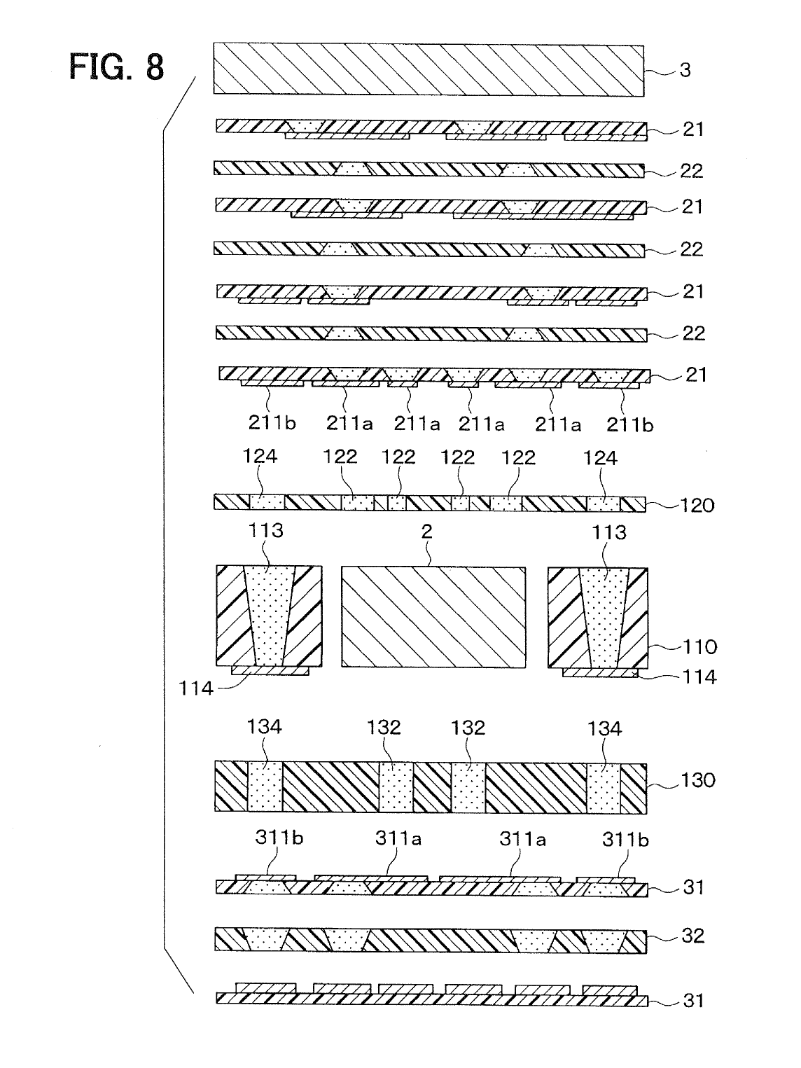

The films 110, 120, 130, 21, 22, 31 and 32 are layered into a layered member of FIG. 8 in a layering process.

At this time, the conductor pattern 114 located on the lower side in the interlayer 11 is made contact with the paste 134 of the adhesive layer 13. The layered member of FIG. 8 is arranged in a pressing machine (not shown), and the heating-and-pressing process is performed.

According to the present embodiment, the conductor pattern 114 is added to the multilayer board of the first embodiment. The conductor pattern 114 opposing to the connector 13b is formed on the face of the interlayer film 110.

Therefore, in the heating-and-pressing process, the paste 134 of the adhesive film 130 is sufficiently compressed by the thickness of the conductor pattern 114, compared with the first embodiment. That is, the compressive force applied to the interlayer connector 13b is increased in the heating-and-pressing process.

Further, the paste 113 of the via hole 112 is also compressed by the conductor pattern 114.

Thereby, the compressive force applied to the connector 13b of the thick layer 13 can be increased. Further, the compressive force applied to the connector 11a of the interlayer 11 can be increased because the conductor pattern 114 is defined on the interlayer 11.

Thus, void can be prevented from being generated in the connector 13b, 11a, so that reliability of interlayer connection can be raised in the thermoplastic resin film layer 10.

### Third Embodiment

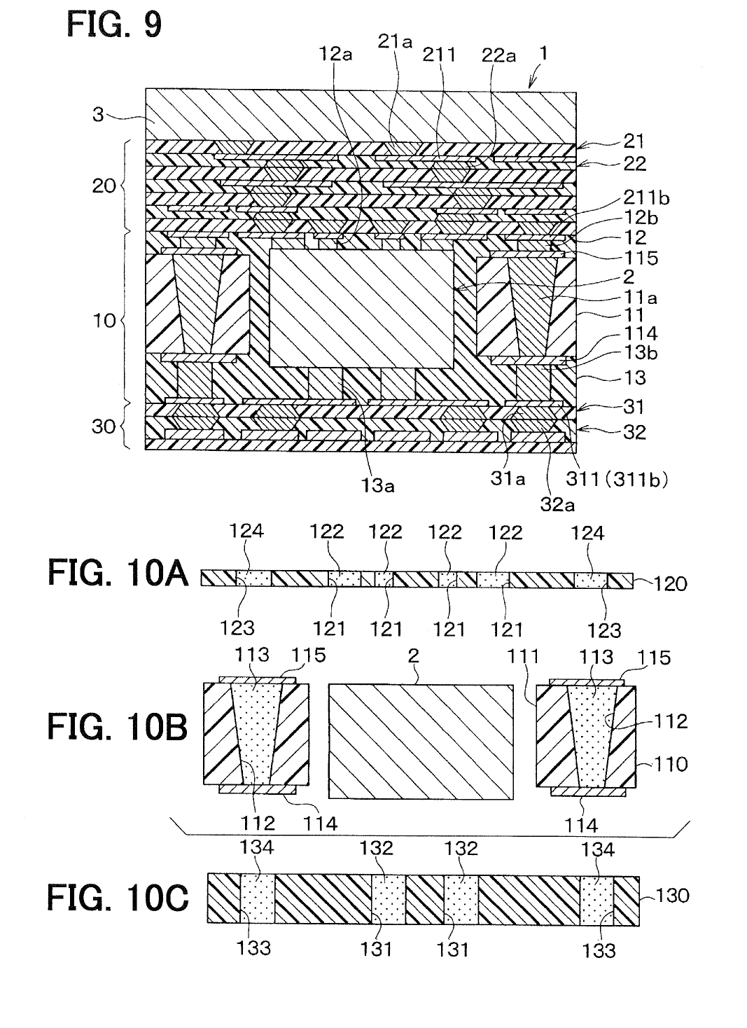

A third embodiment will be described with reference to FIGS. 9-11.

As shown in FIG. 9, a conductor pattern 114 is arranged on a face of the interlayer 11 opposing to the connector 13b of the adhesive layer 13, and a conductor pattern 115 is arranged on a face of the interlayer 11 opposing to the second connector 12b of the adhesive layer 12.

A producing process of the interlayer film 110 of FIG. 10B corresponding to the interlayer 11 of the thermoplastic resin film layer 10 will be described below. A thermoplastic resin film is prepared as an insulating base material. The electronic component 2 is accommodated in the accommodation hole 111, and the paste 113 is filled in the via hole 112.

Further, a copper foil is layered on each of the upper face and the lower face of the interlayer film 110, and etching is performed to the copper foil. Thus, the conductor pattern 114 is defined at the position opposing to the connector 13b, and the conductor pattern 115 is defined at the position opposing to the connector 12b. The conductor pattern 114 corresponds to a base part of the via hole 112, and the conductor pattern 115 corresponds to a lid part of the via hole 112.

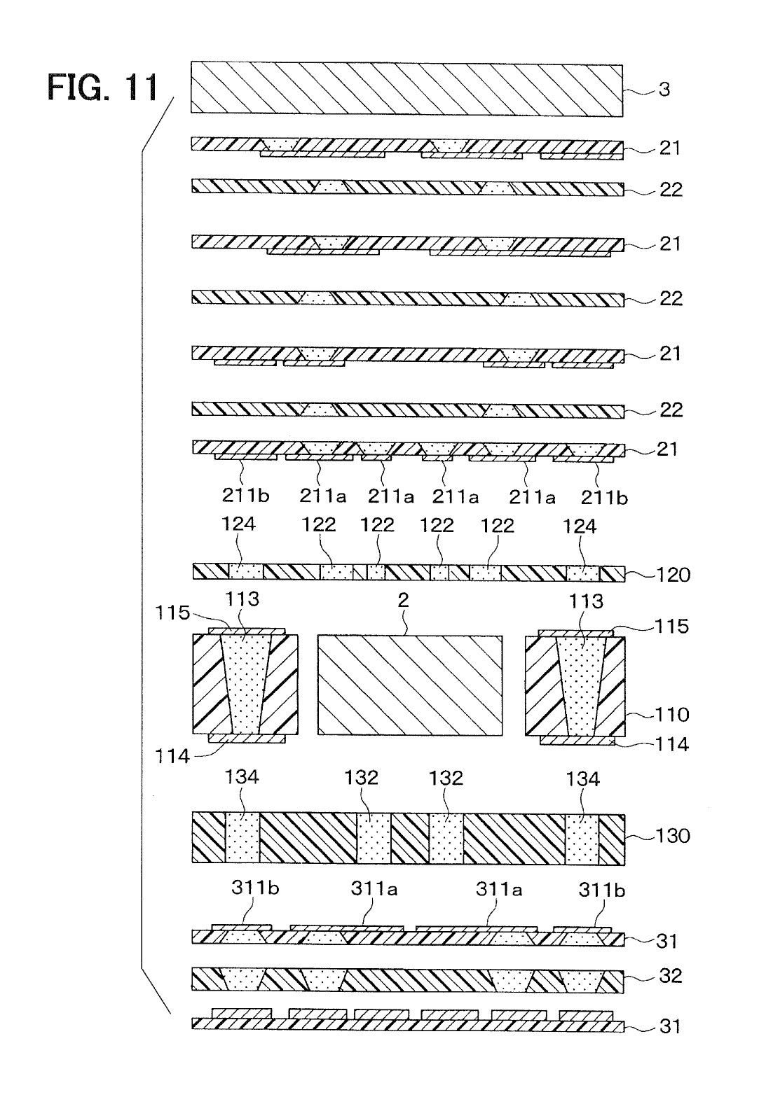

The films 110, 120, 130, 21, 22, 31 and 32 are layered into a layered member of FIG. 11 in a layering process.

At this time, the conductor pattern 114 located on the lower side in the interlayer 11 is made contact with the paste 134 of the adhesive layer 13. Further, the conductor pattern 115 located on the upper side in the interlayer 11 is made contact with the paste 124 of the adhesive layer 12. The layered member of FIG. 11 is arranged in a pressing machine (not shown), and the heating-and-pressing process is performed.

According to the present embodiment, the conductor pattern 115 is added to the multilayer board of the second embodiment. The conductor pattern 115 opposing to the connector 12b is formed on the face of the interlayer film 110.

Therefore in the heating-and-pressing process, the paste 124 of the film 120 is sufficiently compressed by the thickness of the conductor pattern 115, compared with the second embodiment. That is, the compressive force applied to the interlayer connector 12b is increased in the heating-and-pressing process.

Thus, void can be prevented from being generated in the connector 12b, 13b, 11a, so that reliability of interlayer connection can be raised in the thermoplastic resin film, layer 10.

### Fourth Embodiment

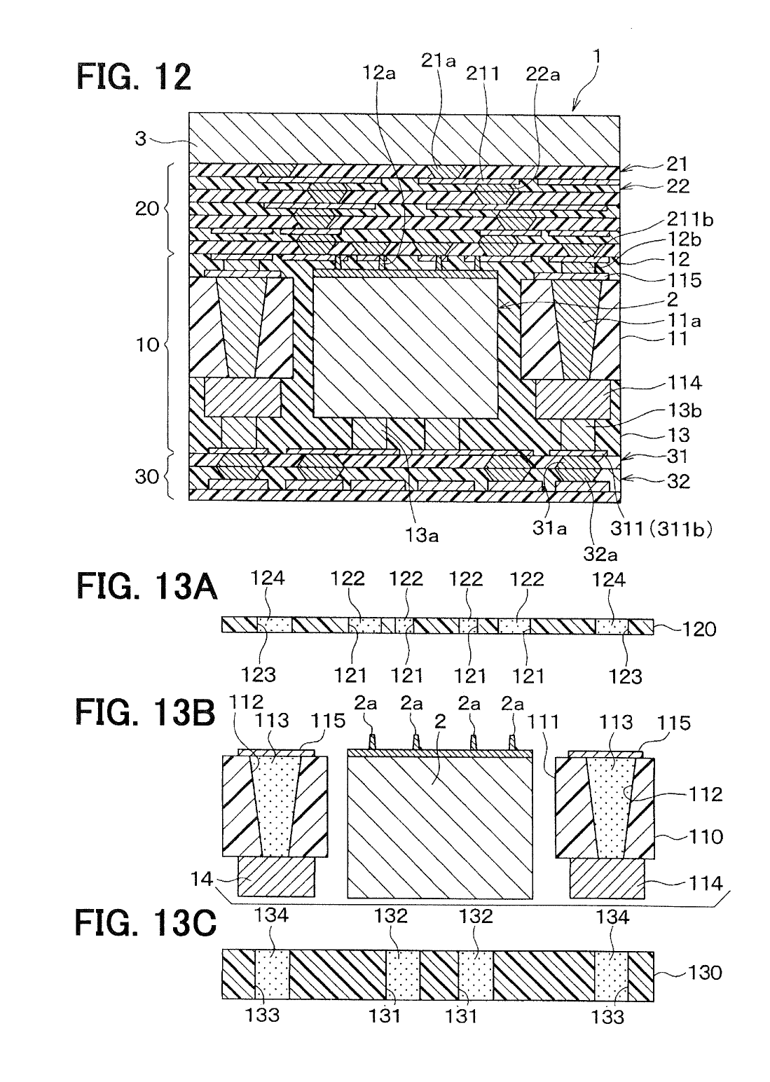

A fourth embodiment will be described with reference to FIGS. 12-14.

As shown in FIG. 12, the connector 12a connects the electrode terminal of the electronic component 2 to the conductor pattern 211a, and is constructed by a stud bump 2a fixed to the electrode terminal of the electronic component 2. The conductor pattern 211a defined on the lowest face of the first pattern layer 20 corresponds to a pad to receive the stud bump 2a. The bump 2a penetrates the paste 122.

Further, the thickness of the conductor pattern 114 opposing to the second adhesive layer 13 is larger than that of the conductor pattern 115 opposing to the first adhesive layer 12.

A producing process of the interlayer film 110 of FIG. 13B corresponding to the interlayer 11 of the thermoplastic resin film layer 10 will be described below. A thermoplastic resin film is prepared as an insulating base material. The electronic component 2 is accommodated in the accommodation hole 111, after the stud bump 2a is fixed on the upper face of the electrode terminal of the component 2. The stud bump 2a is made of gold (Au) wire, for example.

The via hole 112 is defined in the base film by laser beam machining, for example. The via hole 112 passes through the thickness direction. The electric conduction paste 113 is filled in the via hole 112 using a screen printer, for example.

Further, a copper foil is layered on the upper face of the base film, and a copper foil is layered on the lower face of the base film. A thickness of the copper foil bonded to the lower face is larger than that of the copper foil bonded to the upper face. Etching is performed to the copper foils, so that the conductor pattern 114 is defined at the position opposing to the connector 13b, and that the conductor pattern 115 is defined at the position opposing to the connector 12b.

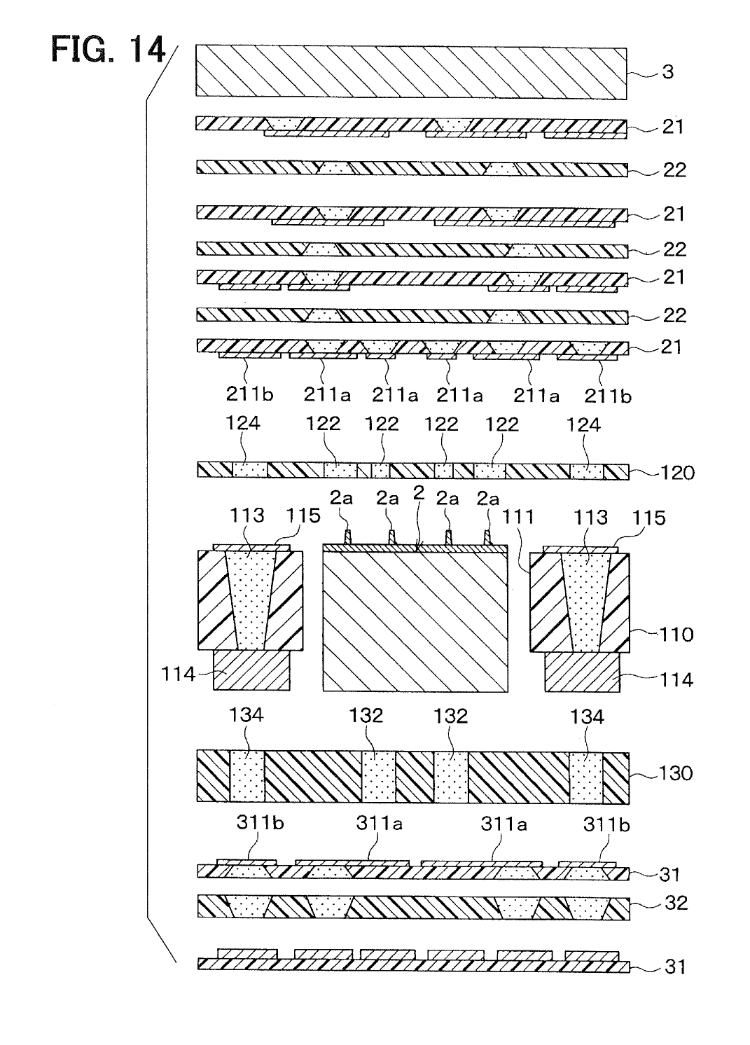

The films 110, 120, 130, 21, 22, 31 and 32 are layered into a layered member of FIG. 14 in a layering process.

At this time, the stud bump 2a passes through the adhesive layer 12. An edge of the bump 2a is connected to the conductor pattern 211a located on the lowest part of the first pattern layer 20.

Further, the conductor pattern 114 located on the lower side in the interlayer 11 is made contact with the paste 134 of the adhesive layer 13. The conductor pattern 115 located on the upper side in the interlayer 11 is made contact with the paste 124 of the adhesive layer 12.

The layered member of FIG. 14 is arranged in a pressing machine (not shown), and the heating-and-pressing process is performed.

According to the present embodiment, the thickness of the conductor pattern 114 is made larger than that of the conductor pattern 115, compared with the third embodiment.

In this case, the amount of resin flowing into a clearance defined between the conductor pattern 114 and the electronic component 2 is increased.

Therefore, the compressive force applied to the interlayer connector 13b, 11a is increased in the heating-and-pressing process.

Thus, void can be prevented from being generated in the connector 12b, 13b, 11a, so that reliability of interlayer connection can be raised in the thermoplastic resin film layer 10.

Further, the connector 12a is constructed by the stud bump 2a.

Therefore, it is not necessary to reduce the thickness of the first adhesive layer 12, compared with the first to third embodiments in which the connector 12a is constructed by conductive paste.

Thus, the connection reliability of the connector 12a can be maintained high, and the compressive force applied to the electronic component 2 can be reduced in the heating-and-pressing process.

### Fifth Embodiment

In a fifth embodiment, films are located between two conductor patterns, and elasticity coefficient and thickness of the films are changed so as to improve the reliability of the interlayer connection.

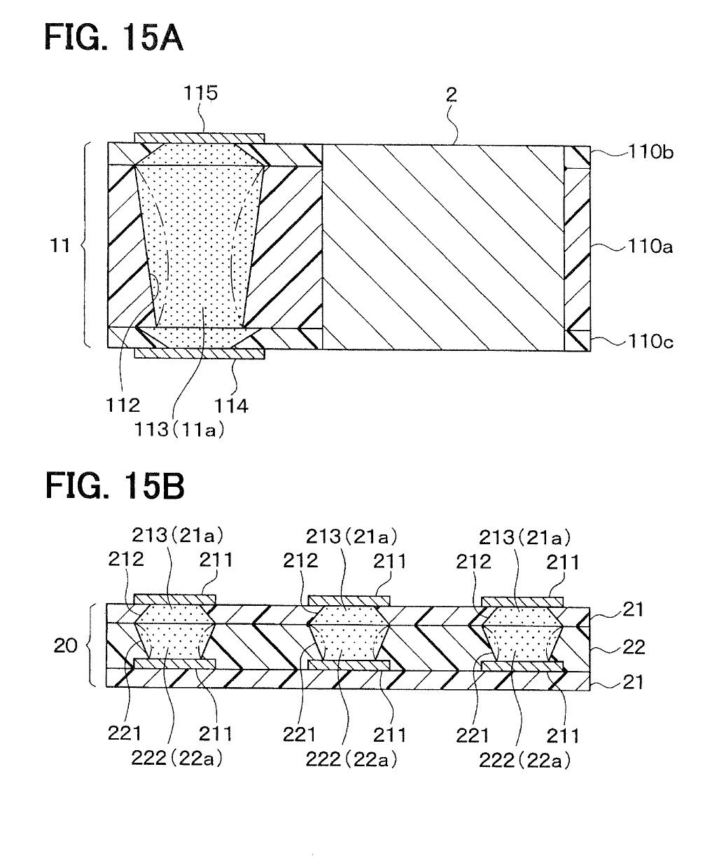

As shown in FIG. 15A, the interlayer 11 is configured to accommodate the electronic component 2, and the conductor patterns 114, 115 are arranged on the both sides of the interlayer 11, respectively, similar to the third embodiment.

The interlayer 11 is made of three films 110a, 110b, 110c in the fifth embodiment, while the interlayer 11 is made of the single film 110 in the third embodiment.

Specifically, the inner film 110a is interposed between the outer films 110b, 110c.

Each of the film 110a, 110b, 110c has a through hole corresponding to the via hole 112. For example, each through hole has a taper shape.

The elasticity coefficient of the inner film 110a is smaller than that of the outer film 110b, 110c at a heating-and-pressing temperature. For example, the elasticity coefficient E′ of the inner film 110a is larger than 1.0E+05Pa, and is less than 1.0E+09Pa (1.0E+05Pa<E′<1.0E+09Pa), at 320° C. The elasticity coefficient E′ of the outer film 110b, 110c is larger than 1.0E+09Pa (E′>1.0E+09Pa), at 320° C.

The inner film 110a has a thickness of t20-500 μm. The outer film 110b, 110c has a thickness of t12.5-50 μm.

The inner film 110a may be made of thermoplastic resin film, and the outer film 110b, 110c may be made of thermosetting resin film.

As shown in FIG. 15B, the first pattern layer 20 is constructed by alternately layering the pattern films 21 and the adhesive film 22, and the upper face of the pattern film 21 has the conductor pattern 211, similar to the first to fourth embodiments.

The elasticity coefficient of the film 22 is smaller than that of the film 21 at a heating-and-pressing temperature. For example, the elasticity coefficient E′ of the adhesive film 22 is larger than 1.0E+05Pa, and is less than 1.0E+08Pa (1.0E+05Pa<E′<1.0E+08Pa), at 320° C. The elasticity coefficient E′ of the pattern film 21 is larger than 1.0E+09Pa (E′>1.0E+09Pa), at 320° C.

The adhesive film 22 has a thickness of t20-300 μm. The pattern film 21 has a thickness of t12.5-50 μm.

The adhesive film 22 may be made of thermoplastic resin film, and the pattern film 21 may be made of thermosetting resin film.

Because the elasticity coefficient of the inner film 110a is smaller than that of the outer film 110b, 110c, as shown in a double-chain line of FIG. 15A, the paste 113 is pressed inward by the inner film 110a in the heating-and-pressing process.

Thereby, the paste 113 is pressed toward the conductor pattern 114, 115. Therefore, the paste 113 is connected to the conductor pattern 114, 115 with high reliability even if the paste 113 has contraction when the metal particles are sintered.

Because the elasticity coefficient of the adhesive film 22 is smaller than that of the pattern film 21, as shown in a double-chain line of FIG. 15B, the paste 222 is pressed inward by the adhesive film 22 in the heating-and-pressing process.

Thereby, the paste 222 is pressed toward the conductor pattern 221. Therefore, the paste 213, 222 is connected to the conductor pattern 211 with high reliability even if the paste 213, 222 has contraction when the metal particles are sintered.

In other words, when a first film and a second film are located between two conductor patterns, elasticity coefficient of the first film is made smaller than that of the second film. Paste in a via hole, is pressed by the first film toward the conductor pattern. Therefore, the paste can be connected to the conductor pattern with high reliability even if the paste has contraction when the metal particles are sintered. Thus, the reliability of the interlayer connection can be improved.

If three films are located between the two conductor patterns, as shown in FIG. 15A, the elasticity coefficient of the inner film 110a may be made smaller than that of the outer film 110b, 110c.

Further, if the films are set to have the above predetermined thickness, the paste can be effectively pressed. Therefore, the reliability of the interlayer connection can be further improved.

The reliability of the interlayer connection can be improved also for the second pattern layer 30, while FIG. 15B shows an example of the first pattern layer 20.

### Other Embodiment

The conductor pattern is not limited to be formed on the pattern layer 20, 30. The conductor pattern may be formed on at least one of a face of the pattern layer 20, 30 and a face of the interlayer 11 at a position opposing to the second interlayer connector 12b, 13b.

The conductor pattern 211, 311 may be formed on both sides of the pattern film 21, 31.

The conductor pattern may be made of conductive metal other than the copper foil.

The interlayer 11 is not limited to accommodate the electronic component 2. The interlayer 11 may accommodate other component.

The heat sink 3 may be eliminated from the multilayer board 1.

Such changes and modifications are to be understood as being within the scope of the present invention as defined by the appended claims.

What is claimed is:

1. A multilayer board comprising:
a thermoplastic resin film layer having a plurality of thermoplastic resin films layered with each other, the thermoplastic resin film being softened at a predetermined temperature;
a pattern layer layered on the thermoplastic resin film layer, the pattern layer having a low-flowability resin film, flowability of the low-flowability resin film being lower than that of the thermoplastic resin film at the predetermined temperature; and
a first conductor pattern having a predetermined thickness, wherein
the thermoplastic resin film layer has a first adhesive layer, a second adhesive layer and an interlayer located between the first and second adhesive layers,
the interlayer has a first interlayer connector passing through the interlayer in a thickness direction,
each of the adhesive layers has a second interlayer connector passing through the adhesive layer in the thickness direction, the second interlayer connector being electrically connected to the first interlayer connector, and
the first conductor pattern is located on at least one of a face of the pattern layer and a face of the interlayer at a position opposing to the second interlayer connector.

2. The multilayer board according to claim 1, wherein
each of the first interlayer connector and the second interlayer connectors is made of conductive material, the conductive material being defined by filling conductive paste in a via hole, the conductive paste containing metal particles sintered with each other,
the first adhesive layer has a thickness larger than that of the second adhesive layer, and
the first conductor pattern is located on the interlayer, and opposes to the second interlayer connector of the first adhesive layer.

3. The multilayer board according to claim 2, further comprising:
a second conductor pattern located on the pattern layer, wherein the second conductor pattern opposes to the second interlayer connector of the first adhesive layer.

4. The multilayer board according to claim 2, further comprising:
a third conductor pattern located on the interlayer, wherein the third conductor pattern opposes to the second interlayer connector of the second adhesive layer.

5. The multilayer, board according to claim 1, further comprising:
an electronic component located in the interlayer, wherein
the second adhesive layer has an electrode connector electrically connected to an electrode terminal of the electronic component.

6. The multilayer board according to claim 1, further comprising:
an electronic component located in the interlayer, wherein
each of the first interlayer connector and the second interlayer connectors is made of conductive material, the conductive material being defined by filling conductive paste in a via hole, the conductive paste containing metal particles sintered with each other,
the first adhesive layer has a thickness larger than that of the second adhesive layer,
the second adhesive layer has an electrode connector electrically connected to an electrode terminal of the electronic component, and
the first conductor pattern is located on the interlayer, and opposes to the second interlayer, connector of the first adhesive layer.

7. The multilayer board according to claim 6, further comprising:
a second conductor pattern located on the pattern layer, wherein the second conductor pattern opposes to the second interlayer connector of the first adhesive layer.

8. The multilayer board according to claim 6, further comprising:
a third conductor pattern located on the interlayer, wherein the third conductor pattern opposes to the second interlayer connector of the second adhesive layer.

9. The multilayer board according to claim 8, wherein
the first conductor pattern has a thickness larger than that of the third conductor pattern.

10. The multilayer board according to claim 5, wherein
the pattern layer has a pad opposing to the electrode connector,
the pad is electrically connected to the electrode connector,
the electrode connector is connected to the electrode terminal of the electronic component, and
the electrode connector is made of a stud bump.

11. The multilayer board according to claim 1, wherein
the low-flowability resin film is made of a thermosetting resin film.

12. The multilayer board according to claim 1, further comprising:
an electronic component located in the interlayer, wherein
the interlayer has the conductor pattern opposing to the second interlayer connector of the first adhesive layer and the conductor pattern opposing to the second interlayer connector of the second adhesive layer,
the first interlayer connector is made of conductive material, the conductive material being defined by filling conductive paste in a via hole, the conductive paste containing metal particles sintered with each other,
the interlayer has an inner film and two outer films alternately layered with each other, and
the inner film has elasticity coefficient smaller than that of the outer film at a heating-and-pressing temperature.

13. The multilayer board according to claim 12, wherein
the elasticity coefficient of the inner film is more than 1.0E+05Pa, and is less than 1.0E+09Pa, at 320° C., and
the elasticity coefficient of the outer film is more than 1.0E+09Pa at 320° C.

14. The multilayer board according to claim 12, wherein
the inner film has a thickness of t20-500 μm, and
the outer film has a thickness of t12.5-50 μm.

15. The multilayer board according to claim 1, wherein
the pattern layer has a plurality of pattern films and an adhesive film located between the pattern films, a face of the pattern film having another conductor pattern made of copper foil,
the pattern film is made of the low-flowability resin film,
each of the pattern film and the adhesive film has a third interlayer connector that electrically connects the conductor, patterns with each other, the third interlayer connector passing through the film in the thickness direction,
the third interlayer connector is made of conductive material, the conductive material being defined by filling conductive paste in a via hole, the conductive paste containing metal particles sintered with each other, and
the adhesive film has elasticity coefficient smaller than that of the pattern film at a heating-and-pressing temperature.

16. The multilayer board according to claim 15, wherein
the elasticity coefficient of the adhesive film is more than 1.0E+05Pa, and is less than 1.0E+08Pa, at 320° C., and
the elasticity coefficient of the pattern film is more than 1.0E+09Pa at 320° C.

17. The multilayer board according to claim 15, wherein
the adhesive film has a thickness of t20-300 μm, and
the pattern film has a thickness of t12.5-50 μm.
